(19) United States
(12) Patent Application Publication
(10) Pub. No.: US 2021/0242098 A1
(43) Pub. Date: Aug. 5, 2021

(54) VARIABLE THICKNESS LID ADHESIVE

(71) Applicant: International Business Machines Corporation, Armonk, NY (US)

(72) Inventors: Tuhin Sinha, Oradell, NJ (US); Stephanie Allard, St-Hyacinthe (CA); Jean Labonte, Cowansville (CA)

(21) Appl. No.: 16/779,971

(22) Filed: Feb. 3, 2020

(51) Int. Cl. H01L 23/10; H01L 23/42; H01L 21/52; H01L 23/498; H01L 25/065; H01L 23/538

(52) U.S. Cl. CPC H01L 23/10; H01L 23/42; H01L 23/5384; H01L 23/49827; H01L 25/0655; H01L 21/52

(57) ABSTRACT

Chip pairs in a semiconductor module have a spacing between them that forms a spacing region. A lid has a lid bottom side and one or more feet. The feet protrude from a periphery of the lid bottom side. A sealband adhesive has a sealband adhesive thickness and adheres the feet to a substrate so the chip pairs are under the lid bottom side and back sides of the chips are in thermal contact with the lid bottom side. A variable thickness lid adhesive connects the substrate in the spacing region to the lid bottom side. The variable thickness lid adhesive has a lid adhesive thickness that is greater than the sealband adhesive thickness by a delta thickness amount. In some embodiments, the lid also has a shortened central lid rib with a bottom. The shorten central lid rib protrudes an extension distance from the lid bottom side into the spacing region. In these embodiments, the variable thickness lid adhesive connects the substrate in the spacing region to the bottom. In some embodiments, the shortened central lid rib is notched.

### BACKGROUND

The present invention relates to packages of semiconductor circuitry, e.g. semiconductor chip packages. More specifically, the invention relates to reducing warpage in semiconductor chip packages.

Organic flip-chip packages warp due to coefficient of thermal expansion mismatch between silicon die(s) and the organic substrate(s) on which the silicon dies are disposed. Warpage behavior for packages or modules, e.g. dies on one or more substrates combined with other circuitry including interconnections, is getting complex with introduction of heterogeneously integrated (HI) components in modules such as dual chip modules, multi-chip modules, chip-scale packages, etc. Components, like silicon bridges, that make up these modules/packages can and often do have different coefficients of thermal expansion, CTE. (Thermal expansion is the tendency of matter to change its shape, area, and/or volume in response to a temperature change.) Thermal expansion of different materials bound together in a module/package can cause the module/package to warp as temperature cycles up and/or down.

Warpage control is critical during the bonding together and assembly of components to form modules/packages. Warpage control is also important during module/package operation when the temperature of the module/package changes. Uncontrolled or badly controlled warpage can cause thermal stresses and strains within the module/package which leads to thermal stress discontinuities, miss alignment of components and internal component structures, bad electrical connections, mechanical failures, electrical failures, and intermittent and permanent failure of the modules/packages.

Warpage control is critical for packages with inter-die silicon bridges and high-speed die-to-die communication channels.

Warpage control becomes increasingly difficult with introduction of especially in multi-chip packages.

Some prior art provides stiffeners to address the warping problem. U.S. Pat. No. 9,089,052 B2 uses a stiffening ring. US patent applications 20080128897A1 and 20090057884A1 integrate a heat spreading lid with a central lid rib in dual chip modules (DCMs) and multichip modules (MCMs).

However, these solutions have shortcomings.

In this prior art, a larger die-die spacing is needed to sufficiently incorporate the lid and/or stiffening structure to bond with the organic substrate in accordance with bond and assembly tolerances for underfill fillet width around the die perimeter.

Also, a larger die-die spacing is needed to have sufficient bonding area between the adhesive/sealband used to attach central lid rib to organic substrate. Without sufficient bonding, the lid-substrate attaching adhesive will peel and fail during thermal cycling in the region between the dies.

Signal transmission delay is proportional to die-die spacing and hence, increased the die-to-die spacing detrimentally affects electrical performance.

Better warpage control is needed for semiconductor modules/packages particularly those modules and packages that contain dual-chips and multiple chips (multi-chips).

### SUMMARY

Embodiments of the present invention include a semiconductor module or package having one or more chip pairs. Each chip pair has a first semiconductor chip and a second semiconductor chip, i.e. a chip. There is a spacing between the first and second chip that forms a spacing region between the first and second chips. The first and second chips each have a chip back side and are disposed on a substrate. A lid has a lid bottom side and one or more feet. The feet protrude from a periphery of the lid bottom side. A sealband adhesive is a structural material with a controlled thickness that adheres the feet to the substrate so the chip pairs are under the lid bottom side and the chip back sides are in thermal contact with the lid bottom side. A variable thickness lid adhesive connects the substrate in the spacing region to the lid bottom side. The variable thickness lid adhesive has a lid adhesive thickness that is greater than the sealband adhesive thickness by a delta thickness amount.

In some embodiments, the lid also has a shortened central lid rib with a bottom. The shortened central lid rib protrudes an extension distance from the lid bottom side into the spacing region. The variable thickness lid adhesive connects the substrate in the spacing region to the bottom. In some embodiments, the shortened central lid rib is notched.

Methods of making are disclose

### BRIEF DESCRIPTION OF THE DRAWINGS

Various embodiments of the present invention will be described below in more detail, with reference to the accompanying drawings, now briefly described. The Figures show various apparatus, structures, and related method steps of the present invention.

FIG. 1 is an elevation view of an example module/package with multiple semiconductor chips (chips).

FIG. 2 is a top view of an example module/package with multiple chips.

FIG. 3 is a graph showing percent thermal interface material (TIM) strain versus die-to-die spacing at inner and outer corners of chips in a module/package.

FIG. 4 is a graph showing the warpage variation in a region between two chips/dies as a function of die-to-die spacing.

FIG. 5 is an elevation view of one embodiment of a module/package with a lid having a shortened central lid rib and a variable thickness lid adhesive.

FIG. 5A is a top view of an example embodiment looking through the lid of a DCM showing the effects of cutouts on stresses and strains on the DCM.

FIG. 6 is an elevation showing a partial cross section view of an embodiment of a module/package including a notch in the shortened central lid rib.

FIG. 7 is a double graph showing a TIM inner corner strain and sealband peeling stress as a function of sealband BLT delta.

FIG. 8 is a graph showing warpage at the bottom surface metallurgy (BSM) of the chips/dies.

FIG. 9A is a plan view of a dual chip module (DCM) layout with the first and second chip/die being approximate the same size.

FIG. 9B is a plan view of a dual chip module (DCM) layout with the first and second chip/die being different sizes.

FIG. 10A is a plan view of a mult-chip module (MCM) layout with the three adjacent chip/dies of the same size.

FIG. 10B is a plan view of a mult-chip module (MCM) layout with the three adjacent chip/dies of the different sizes.

FIG. 10C is a plan view of a mult-chip module (MCM) layout with the three adjacent chip/dies of the approximately the same size.

FIG. 11A is a plan view of a mult-chip module (MCM) layout with the four chip/dies in a row with respective shortened central lid ribs between them.

FIG. 11B is a molt-chip module (MCM) layout with the four chip/dies of approximately equal size and shape laid out in a rectangular or square pattern.

FIG. 11C is a molt-chip module (MCM) layout with the four chip/dies of approximately equal size and shape laid out in a rhombus or parallelogram pattern.

FIG. 11D is a molt-chip module (MCM) layout with the four chip/dies of approximately equal size and shape laid out in a “T” pattern.

FIG. 11E is a mull-chip module (MCM) layout, with the four chip/dies laid out in a “plus” pattern

FIG. 12 is a flow chart showing the method steps of a process of making a module/package with a variable thickness adhesive.

### DETAILED DESCRIPTION

It is to be understood that embodiments of the present invention are not limited to the illustrative methods, apparatus, structures, systems and devices disclosed herein but instead are more broadly applicable to other alternative and broader methods, apparatus, structures, systems and devices that become evident to those skilled in the art given this disclosure.

In addition, it is to be understood that the various layers, structures, and/or regions shown in the accompanying drawings are not drawn to scale, and that one or more layers, structures, and/or regions of a type commonly used may not be explicitly shown in a given drawing. This does not imply that the layers, structures, and/or regions not explicitly shown are omitted from the actual devices.

In addition, certain elements may be left out of a view for the sake of clarity and/or simplicity when explanations are not necessarily focused on such omitted elements. Moreover, the same or similar reference numbers used throughout the drawings are used to denote the same or similar features, elements, or structures, and thus, a detailed explanation of the same or similar features, elements, or structures may not be repeated for each of the drawings.

The semiconductor devices, structures, and methods disclosed in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, expert and artificial intelligence systems, functional circuitry, neural networks, etc. Systems and hardware incorporating the semiconductor devices and structures are contemplated embodiments of the invention.

As used herein, “height” refers to a vertical size of an element (e.g., a layer, trench, hole, opening, etc.) in the cross-sectional or elevation views measured from a bottom surface to a top surface of the element, and/or measured with respect to a surface on which the element is located.

Conversely, a “depth” refers to a vertical size of an element (e.g., a layer, trench, hole, opening, etc.) in the cross-sectional or elevation views measured from a top surface to a bottom surface of the element. Terms such as “thick”, “thickness”, “thin” or derivatives thereof may be used in place of “height” where indicated.

As used herein, “lateral,” “lateral side,” “side,” and “lateral surface” refer to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

As used herein, terms such as “upper”, “lower”, “right”, “left”, “vertical”, “horizontal”, “top”, “bottom”, and derivatives thereof shall relate to the disclosed structures and methods, as oriented in the drawing figures. For example, as used herein, “vertical” refers to a direction perpendicular to the top surface of the substrate in the elevation views, and “horizontal” refers to a direction parallel to the top surface of the substrate in the elevation views.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop,” “disposed on,” or the terms “in contact” or “direct contact” means that a first element and a second element are connected without any intervening elements, such as, for example, intermediary conducting, insulating or semiconductor layers, present between the first element and the second element.

It is understood that these terms might be affected by the orientation of the device described. For example, while the meaning of these descriptions might change if the device was rotated upside down, the descriptions remain valid because they describe relative relationships between features of the invention.

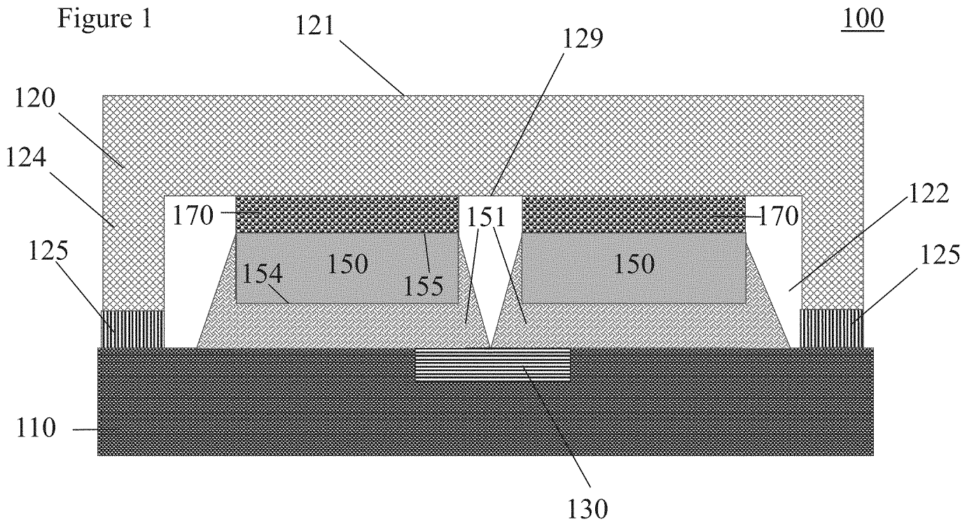

FIG. 1 is an elevation view of an example module/package 100 with multiple semiconductor chips (chips).

The package 100 comprises a substrate or chip carrier 110. The substrate/chip carrier 110 can be made of organics, dielectrics, FR-4, epoxy resin, glass epoxies, polycarbonates, polyimides, polyurethanes, laminates, laminated organics, ceramics, etc. The chip carrier 110 provides support for the components of the package 100 and can include interconnections and/or other circuitry within laminated layers.

One or more chips 150 are disposed on the chip carrier 110. The chips 150 have a connection side 154 with one or more external connections (not shown) and a backside 155. Typically, the connections on the connection side 154 connect to connections on the chip carrier 110. The backside 155 is the side of the chip 150 opposite the chip carrier 110. Examples of external electrical (and physical) connections are C4 bonds.

In some embodiments there is an underfill 151 material disposed between the connection side 154 and chip carrier 110. The underfill 151 fills the space between the chip 150 and the chip carrier 110 and provides structure support to the module/package 100.

Modules/packages containing chip carriers 110, chips 150, connections, and underfill 151 are known.

During operation and assembly, some components of the module/package 100, e.g. the chips 150, experience temperature cycling. As discussed above, the temperature cycling causes stresses and strains within the module/package 100 due to factors like differences of the CTE of the components.

A lid 120 is a structure with relatively large thermal mass and good heat conducting properties. The lid 120 has one or more feet 124, a lid top side 121, and a lid bottom side 129. Typically, the feet 124 protrude from the lid bottom side 129 on the periphery of the lid bottom side 129. The feet 124 can be individual or can surround the lid bottom side 129 around the periphery of the lid bottom side 129 in a continuous fashion. The feet 124 are structurally attached to the substrate/chip carrier 110 by lid adhesive or sealband 125. The lid bottom side 129 and feet 124 form a chip region 122 in which the chips 150 reside when the lid 120 is disposed on the substrate/chip carrier 110 and the sealband 125 connects the lid 120 and the substrate/chip carrier 110. The chips 150 backsides 155 are in thermal contact with the lid bottom side 129 through a thermal interface material (TIM) 170.

The lid 120 bottom side 129 is in physical contact with the TIM 170 which is in turn in physical contact with the chip 150 backside 155 thus forming a thermal pathway for the conduction of heat from the chip 150 through the TIM 170 to the lid 120. The TIM 170 is disposed within and fills the chip region 122 between the lid 120 bottom side 129 and the chip backside 155. Non-limiting examples of the TIM 170 include: a thermal pad typically made of silicone or other materials, a compressible pad, a compressible sheet, a polymer in paste or gel form, and a liquid metal such as Indium-Gallium.

Some embodiments use silicon-bridge technology 130, enabled by 2.5D and 3D integration, on the chip carrier 110 to support high-bandwidth communication between chips via the bridge 130. Bridges 130 can serve as an in-package interconnect for multiple-die modules/packages 100. Bridges 130 are known and can be configured various ways, e.g. stacked upon and/or adjacent to one another. Bridges 130 have internal connections, e.g. for connecting chip 150 to chip 150 and/or through connections, e.g. through-silicon vias (TSVs). The CTE of the bridge 130 material, e.g. silicon, also has an affect on module/package 100 warping, particularly when the substrate/chip carrier 110 and bridge 130 are made of materials with largely different CTEs.

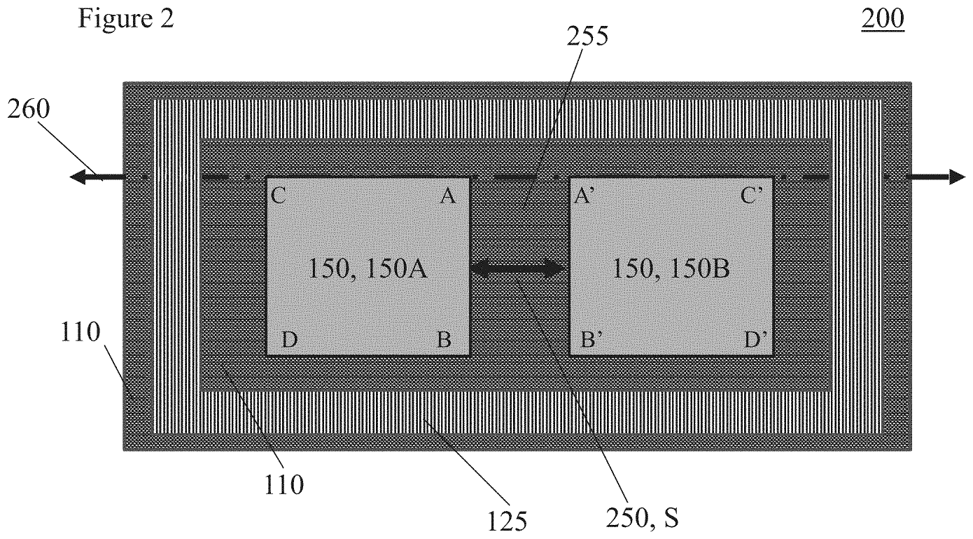

FIG. 2 is a top view (through the lid 120) of an example module/package 200 with multiple chips 150. In this example two dies or chips 150 are separated by a die-to die spacing (250, S).

The presence of two adjacent chips/dies 150 creates curvature changes in the chip carrier 110 between the chips/dies 150. The amount of curvature change is related to the die-to-die spacing (250, S). Curvature change can occur during operation when there is differential heating within the module/package (100, 200). For example, as the chips/dies 150 heat up, the region around (e.g., above and below) the chips/dies 150 becomes hotter than the spacing 250 between the chips/dies 150. The combination of differential heating and differences in the CTEs of materials of the components used in the module/package (100, 200) will cause the curvature change or warping of the chip carrier 110 and other components in the module/package (100, 200).

Note that FIG. 2 is an example case with two chips/dies 150 and one spacing region 255 between them. In other examples contemplated, more than two chips/dies 150 are within the module/package which creates multiple spacing regions 255 between chips/dies 150. Chips/dies 150 stacked in a vertical direction can also cause warping.

The chips/dies 150 have corners, A, B, C, D on a first chip 150A and A′, B′, C′, and D′ on a second chip 150B. Inner corners A and A′ are corresponding inner corners. Inner corners B and B′ are also corresponding inner corners. Outer corners C and C′ are corresponding outer corners and outer corners D and D′ are corresponding outer corners. Chips/dies 150A and 150B are chip pairs that have a spacing region 255 between them.

Due to many factors, e.g, location of the heat sources) within the chips/dies 150; the thermal conductive, k, of the materials; layout geometries; etc., the differential heating in the spacing region 255 between the chips/dies 150 changes as the region 255 is linearly traversed between the top corresponding inner corners (A, A′) and the bottom inner corners (B, B′). Accordingly, the warpage changes in the region 225 as the linear traversal is made from the top inner corners (A, A′) anywhere in the region 225 to the bottom inner corners (B, B′). Warpage can be measured in the spacing region 255 between the chips/dies 150 along any specific distance between chip edges, e.g, between edge AB and edge A′B′. For example, warpage and other physical changes can be measured along line 260, between corresponding corners A and A′ or along the top edges (AC and A′C′) of the chips/dies 150.

Warpage in the region 225 causes many detrimental effects in the module/package (100, 200). For example, warpage can cause the sealband 125 to peel away from the substrate/chip carrier 110 and/or the feet 124 of the lid 120. In addition, warpage can cause the thermal interface material (TIM) 170 to peal away from the chip 150 backside 155 and/or the lid bottom side 129, causing a disruption in the path heat flow away from the chips/dies 150.

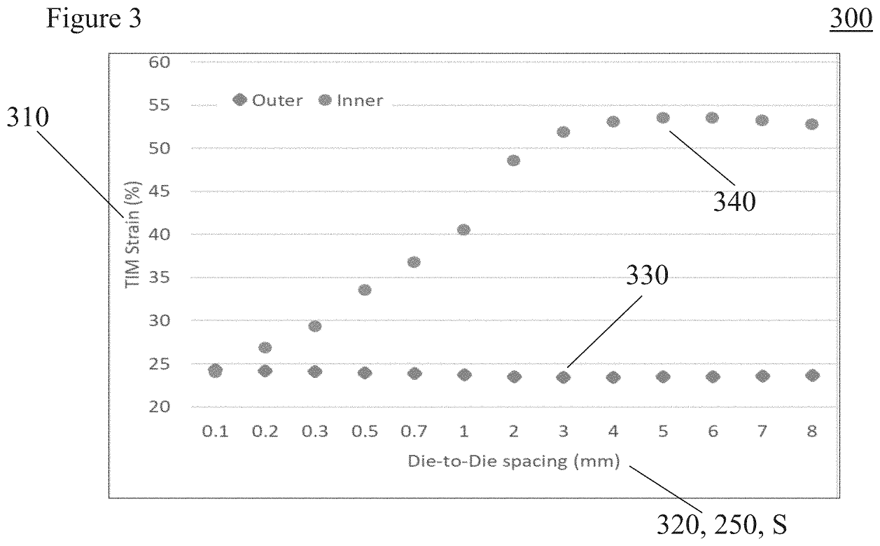

FIG. 3 is a graph 300 showing percent thermal interface material (TIM) strain 310 as a function of die-to-die spacing (320, 250, S) between the inner corners (A, A′) of the chips/dies 150 along the top edges 260. The plots assume that there is full underfill to die sidewall adhesion even for die-to-die spacing, S, below 1 millimeter (mm).

Examination of the graph 300 reveals that there is very little change 330 in the TIM strain 310 at the top outer corners (C and C′) with respect to changes in the die-to-die spacing (320, 250, 5). However, there is a dramatic increase 340 in the TIM strain 310 with respect to changes in the die-to-die spacing (320, 250, S) at the top inner corners (A and A′). In the spacing region 255 between the top inner corners (A, A′), the TIM percent strain is about 25% when the spacing, S, is 0.1 mm but increases to nearly 55% when the die-to-die spacing, S, increases to 5 mm.

These results indicate that the chips 150 should be spaced, S, as close as possible to minimize stress on the TIM 170. However, die-to-die spacing (320, 250, S) is dictated by electrical design requirements. Spacing the chips 150 too close together can cause thermal challenges. Also, the module/package (100, 200) depends on the underfill to die sidewall adhesion for module/package (100, 200) integrity. Spacing the chips 150 too close together reduces this integrity.

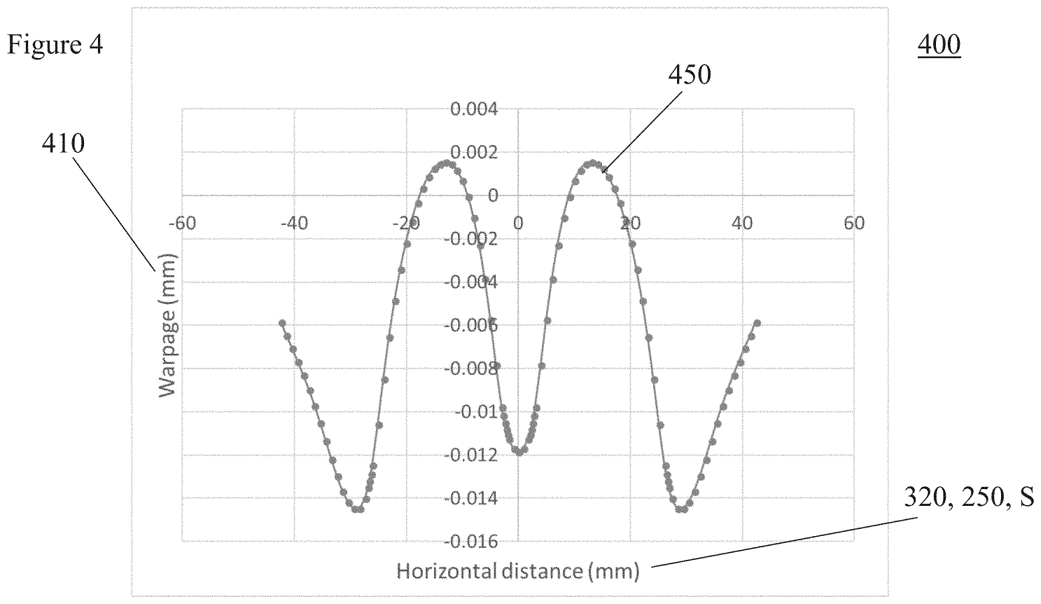

FIG. 4 is a graph 400 showing the warpage variation in mm 410 as a function 450 of die-to-die spacing (320, 250, S) in mm between the inner corners (A, A′) of the chips/dies 150 along the top edges 260. The graph 400 shows wide swings in warpage with respect to die-to-die spacing (320, 250, S), e.g. warpage swings between about −0.0145 mm and +0.002 mm. Warpage can vary between about −0.012 mm and +0.002 mm as the die-to-die spacing, S, varies from 0 mm to about 10 mm.

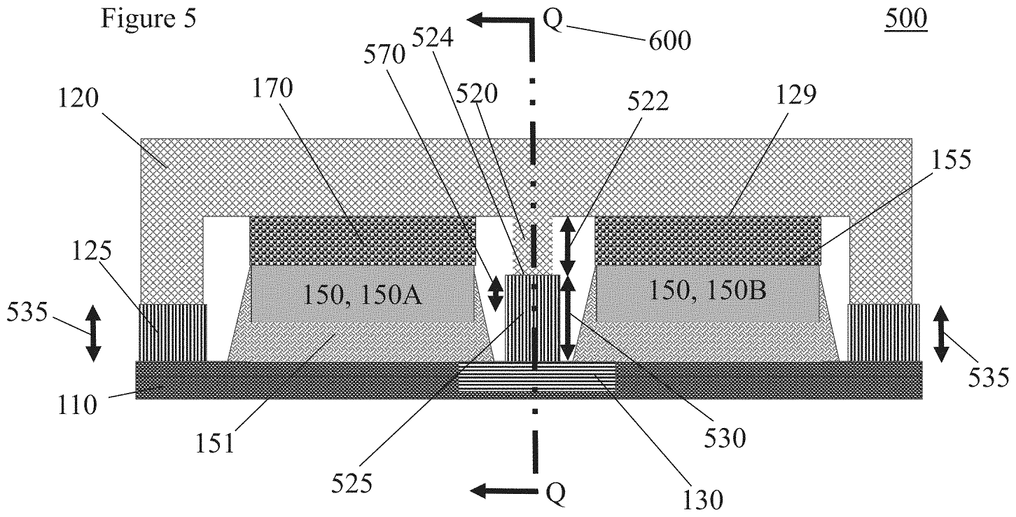

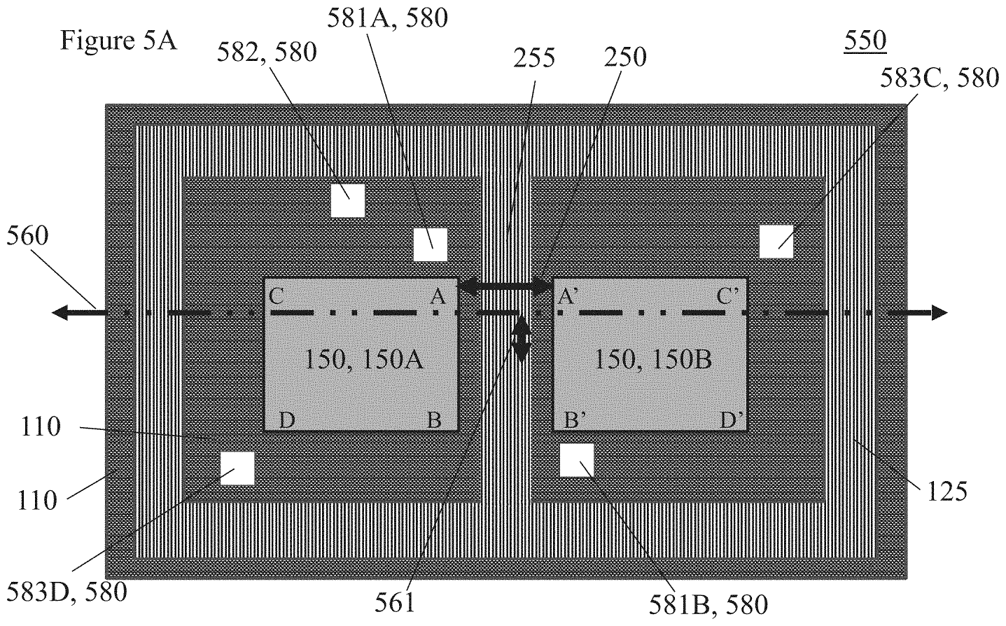

FIG. 5 is an elevation view of one embodiment of a module/package 500 with a lid 120 having a shortened central lid rib 520 and a variable thickness lid adhesive 525.

The shortened central lid rib 520 is part of the lid 120 and extends down from the lid bottom side 129 between the first 150A and the second 150B chip/die 150. In modules/packages (100, 200, 500) with more than two chips/dies 150, e.g. multi-chip modules MCMs, there can be more that one shortened central lid rib 520. In these cases, each one of shortened central lib ribs 520 extends down from the lid bottom side 129 between a pair of a first 150A and a second 150B chip/die 150.

The shortened central lid rib 520 extends an extension distance 522 below the lid bottom side 129. In some embodiments, the shortened central lid rib 520 does not extend below the chip 150 backside 155 so that the shortened central lid rib 520 does not interfere with moving the first 150A and second chips 150B together in order to decrease the die-to-die spacing, (250, S).

In addition, a variable thickness lid adhesive 525 is disposed between a bottom 524 of the shortened central lid rib 520 and the top of the substrate/chip carrier 110 and/or the top of the bridge 130. The variable thickness lid adhesive 525 physically attaches the bottom 524 of the shortened central lid rib 520 to the top of the substrate/chip carrier 110 and/or the top of the bridge 130. In addition, the variable thickness lid adhesive 525 can be thermally conductive to provide a heat path from the substrate/chip carrier 110 and/or the top of the bridge 130 to the lid 120.

The variable thickness lid adhesive 525 can be made of the same adhesive material as the sealband 125. These adhesives are well known. However, the variable thickness lid adhesive 525 will be thicker 530 than the thickness 535 of the sealband adhesive 125 by a delta thickness 570 amount. In some embodiments, the sealband 125 adhesive thickness 535 is between 120 and 200 microns. The delta thickness 570 amount is between 80 and 100 microns with the variable thickness lid adhesive 525 being thicker between the dies 150. Note that the thicknesses 530 of the variable thickness lid adhesive 525 and the thicknesses 535 of the sealband 125 are also referred to as Bondline Thicknesses (BLT, 530, 535). The BLT also denotes the thickness of the TIM 170 over the dies 150.

Non-limiting examples of adhesives that can be used as sealband adhesives 125 as well as variable thickness lid adhesive 525 include: Epoxies (e.g. Ablebond 84-3, Masterbond, Loctitle 965-1L) and Silicones such as Dow EA 6700.

In alternative embodiments, the sealband adhesives 125 can be different than the variable thickness lid adhesive 525. For example, the variable thickness lid adhesive 525 be made of a higher strength material. A non-limiting list of these high strength materials include: Masterbond and Loctitle 965-1L.

In some embodiments, using high strength sealband everywhere (125 and 535) will reduce warpage but increase chip to package interaction (CPI) stresses. Using a high strength sealband only in the variable lid adhesive region 525 will provide warpage control but with minimum impact on package stresses (CPI).

Sealband adhesive 125 and variable thickness lid adhesive 525 can be dispensed sequentially using Auger or air-pressure pumps, depending on type of material. To achieve different thicknesses, variable dispense rate or a multiple pass dispense may be used. Viscosity of the material may require using one or a combination of these dispense techniques.

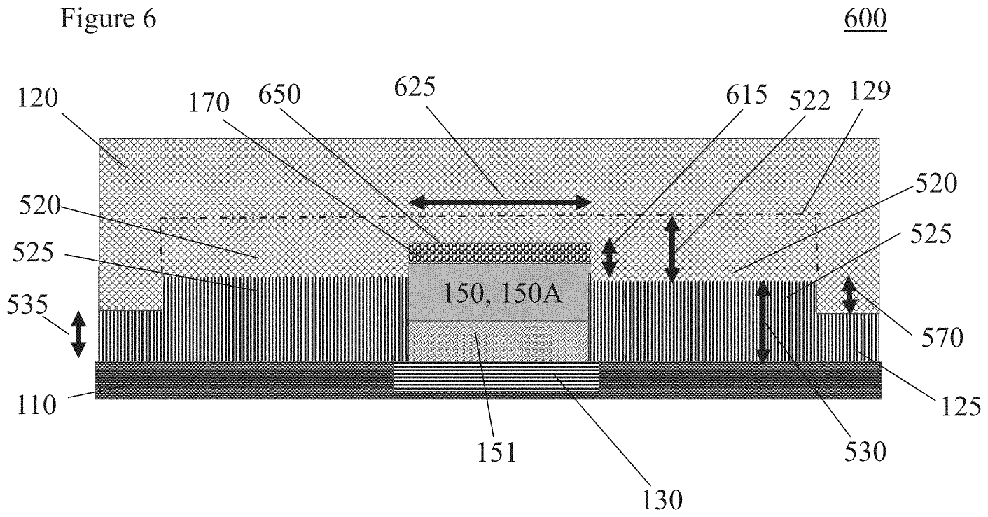

Section Q-Q is a cross-section elevation view 600 that is further described in the description of FIG. 6 below.

FIG. 5A is a top down view of an example: embodiment 550 looking through the lid 120 of a DCM showing the effects of cutouts on stresses and strains on the DCM.

Cutouts (typically 580) are openings in the chip carrier 110 and/or adhesive layer 125 that accommodate components (e.g. resistors, capacitors, etc.) used in the modules. The size and location of these cutouts has an effect on the stresses and strains imposed on the chips 150 and BLTs (125, 525) in the module. For example, cutouts 580 located away from the spacing regions 255, e.g. 583C and 583D, have relatively little effect (low CPI risk) on the stresses, strains, and warping in the spacing regions 255. However, cutouts 580 close to the spacing regions 255, e.g. 581A and 581B, can have a high CPI risk. Cutouts 580 moderately close to the spacing regions 255, e.g. 582, can have a moderate CPI risk in the spacing regions 255 but this CPI risk can increase to a high CPI risk if moderately close cutouts 582 exists with close (581A, 581B) cutouts.

To address the increased CPI risks caused by cutouts 580, the cutouts 580 can be placed away from the spacing regions 255. In addition, as explained in more detail below, the BLT can be increased and/or varied.

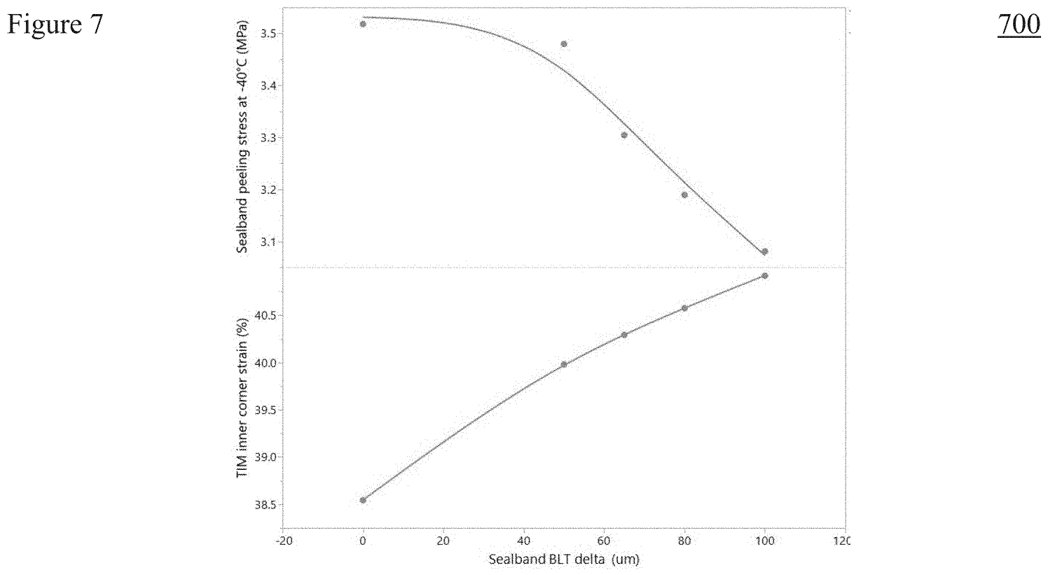

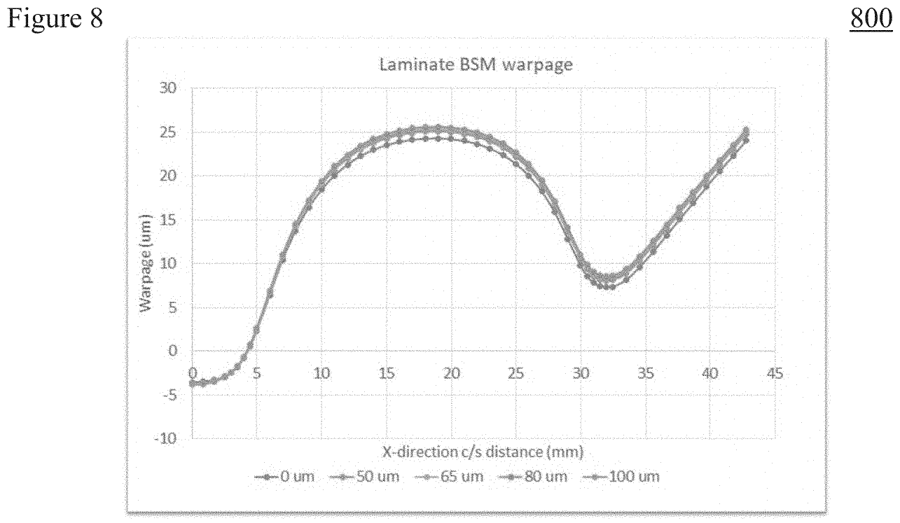

Line 560 is a traverse through the spacing region 255 a distance 561 from the center line of the chips 150. Warpage along this traverse line 560 as a function of the center line distance 561 of the traverse line 560 for different notch depths 615 (below) and will be discussed in the description of FIGS. 7 and 8.

The present invention enables a smaller die-die spacing (250, S) while still having the benefits of a shortened central lid rib 520 between a first 150A and second 150B chip/die 150. The smaller die-die spacing (250, S) reduces the TIM strain 310 and reduces warping. This results in a more reliable and better module/package (100, 200, 500) performance. The risk of tearing the sealband formed by the variable thickness lid adhesive 525 is also reduced. The invention also reduces CPI and reduce warpage in the presence of cutouts 580.

The invention has the uses in modules/packages (100, 200, 500) containing components such as: serial electrically erasable programmable read-only memory (Seeproms), wafer-level chip-scale packaging (WLCSPs), thin small outline packages (TSOPs), mini small-outline package (MSOPs), etc., and boosts their electrical performance.

FIG. 6 is an elevation showing a partial cross section Q-Q view 600 of one embodiment of the module/package 500 including a notch 650 in the (shortened central) lid rib 520.

This view shows the variable thickness lid adhesive 525 with a variable thickness lid adhesive thickness 530 and the sealband adhesive 125 with a thinner sealband adhesive thickness 535 and the delta thickness 570 amount.

In these embodiments, there is a notch 650 in the shortened central lid rib 520. The notch 650 has a notch thickness or depth 615. The notch thickness or depth 615 is an amount that reduces the extension di stance 522 that the shortened central lid rib 520 extends below the lid bottom side 129 in the notch 650 region. The notch 650 has a notch width 625. The notch 650 can be positioned in any location along the shortened central lid rib 520.

In FIG. 6 the variable thickness lid adhesive 525 is not shown in front of the chip/die 150, underfill 151, and part of the TIM 170, so they can be shown for illustration. In some embodiments, the variable thickness lid adhesive 525 would fill this space between the first 150A and second 150B chip/die 150 below the shortened central lid rib 520. The chip/die 150, underfill 151, and TIM 170 would not be visible in this view. In addition, the variable thickness lid adhesive 525 thickness 530 would be thicker under the notch 650 than the other locations under the shortened central lid rib 520.

In some embodiments, the notch 650 thickness 615 can be between 50 micrometers (pm) and 100 μm. Other notch thicknesses 615, particularly thicker ones, are envisioned.

The thicker variable thickness lid adhesive or thicker BLT adds more material under the notch 650 in the shortened central lid rib 520. Because more material under the notch 650 increases the cross-sectional area of the adhesive, the strain is reduced in the area under the notch 650 for the same applied load due to CTE mismatch, Accordingly, by varying the BUT in selected regions of the variable thickness lid adhesive 525, strain caused by thermal cycling, CTE mismatch, cutouts 580, and/or other mechanisms is reduced and warpage is controlled. See a further discussion in FIGS. 7 and 8.

FIG. 7 is a double graph 700 showing TIM inner corner (e.g. A and A′ in FIG. 3) strain in percent and sealband 125 peeling stress at 40 degrees Celsius in megapascais (MPa) as a function of notch 650 depth/thickness 615 in μm. The variation in maximum values is a function of inter-die sealband BLT delta is plotted.

As the notch 650 thickness 615 increases from 0 to 100 μm, the sealband 125 peeling stress decreases from about 3.5 MPa to about 3.1 MPa. However, for the same domain of notch 650 thicknesses 615, the TIM inner corner strain increased from about 38.5% to about 41%. This data assumes that the notch 650 is approximately centered with the first 150A and second 150B chips/dies and has a notch width 625 approximately the width as the side of the chips/dies 150, e.g. side AB.

As an example, as the notch depth 615 approaches 100 μm, the BLT of the variable thickness lid adhesive 525 increases to more than 250 μm. This increased BLT increases the cross-section area of the variable thickness lid adhesive 525 so that the pealing stress is reduced. These strains can he caused by multiple factors including the die-to-die spacing 250, cutouts 580, CTE mismatch, thermal cycling swings, etc.

However, while these strains can he reduced by increasing the notch depth 615 and increasing the BLT of the variable thickness lid adhesive 525, there is a penalty to be paid—the TIM inner corner strain increases. Accordingly, in some embodiments, design constraints are chosen to increase the variable thickness 530 of lid adhesive 525, e.g. in the region of the chip 150, by increasing the notch 650 depth 615 but only until the point where the TIM inner corner strain increases to but remains below a TIM inner corner strain limit. In some embodiments, the TIM inner corner strain limit is in the range between 50% to 90% depending on the specific TIM material.

FIG. 8 is a graph 800 showing laminate 110 warpage in μm in at the bottom surface metallurgy (BSM) of the chips/dies 150, e.g. at the chip/die contacts, at various notch 650 thicknesses 615 in μm as a function of distance traversed 560 across the chips/dies 150 and spacing region 255. The traverse 560 is made along a line 560, 9.6125 mm 561 from the chip 150 center lines.

Inspection of the graph 800 reveals that while warpage increases from −5 μm to about 25 μm during the traverse from a first chip 150 toward a second chip 150 a distance of 25 mm, the warpage changes gradually and varies less than 5 μm from 10 mm to 25 mm along the traversal.

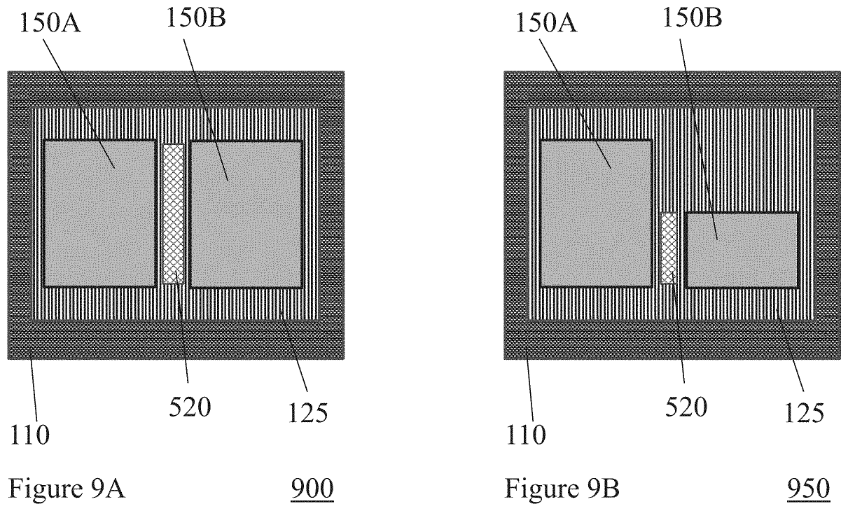

The shortened central lid rib 520 structure and a variable thickness lid adhesive 525 can be used in many different module/package configurations. Non-limiting examples of these configurations are shown in FIGS. 9A, 9B, 10A, 10B, 10C, 11A, 11B, 11C, 11D, and 11E. Each of these figures are a plan view at different elevations in the module/package chosen to show the layout more clearly. The views are not meant to accurately show the component cross sections at any given horizontal plane.

FIG. 9A is a plan view of a dual chip module (DCM) layout 900 with the first 150A and second 150B chip/die approximately the same size. The chips/dies 150 are on a substrate/chip carrier 110 with a sealband 125 or variable thickness lid adhesive 525. The shortened central lid rib 520 sits between the first and second chips/dies 150.

FIG. 9B is a plan view of a dual chip module (DCM) layout 950 with different first 150A and second 150B chip/dies. The chips/dies 150 are on a substrate/chip carrier 110 with a sealband 125 or variable thickness lid adhesive 525. The shortened central lid rib 520 sits between the first and second chips/dies 150 and has the length of the shorter side of the smaller chip/die 150B.

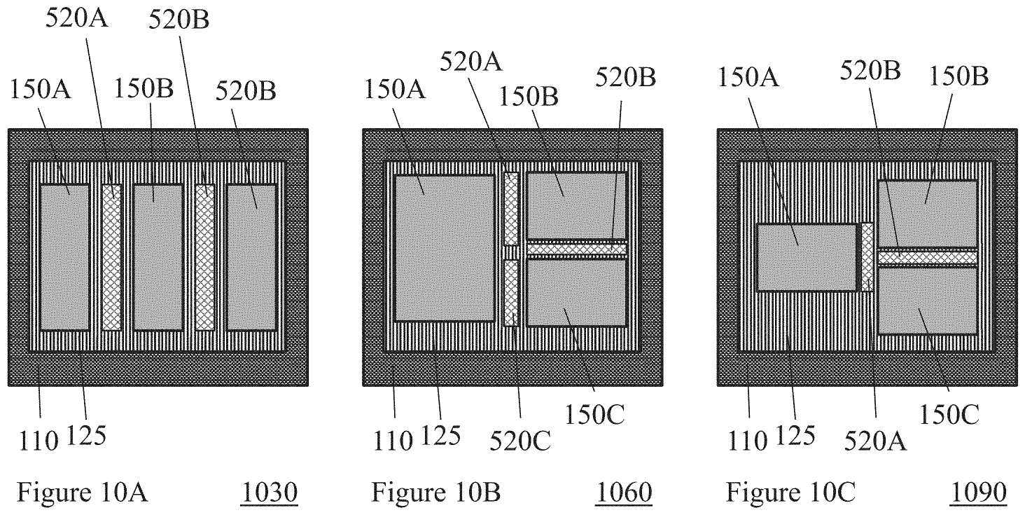

FIG. 10A is a plan view of a mult-chip module (MCM) 1030 layout with the three adjacent chip/dies (150A, 150B, 150C, typically 150) of the same size. The shortened central lid rib 520A is between chip/dies 150A and 150B and the shortened central lid rib 520B is between chip/dies 150B and 150C.

FIG. 10B is a plan view of a molt-chip module (MCM) 1060 layout with the three adjacent chip/dies (150A, 150B, 150C, typically 150) of the different sizes. Chip/die 150A is a larger chip with a long side adjacent to the shorter sides of smaller chip/dies 150B and 150C. The shortened central lid rib 520A is between chip/dies 150A and 150B and the shortened central lid rib 520C is between chip/dies 150A and 150C, each of shortened central lid ribs 520A and 520C is a length approximately equal to the length of the short sides of chip/dies 150B and 150C. respectively. A longer shortened central lid rib 520B is between the longer sides of chip/dies 150B and 150C. The layout is in a “pi” shape, e.g. laying on its side.

FIG. 10C is a plan view of a milt-chip module (MCM) 1090 layout with the three adjacent chip/dies (150A, 150B, 150C, typically 150D) of the approximately the same size. Chip/die 150B and 150C are adjacent on their longer sides with a shortened central lid rib 520B between them. The short side of chip 150A is adjacent and in common with the short sides of chip/dies 150B and 150C with a shortened central lid rib 520A between them. The layout is in a “T” shape, e.g. laying on its side.

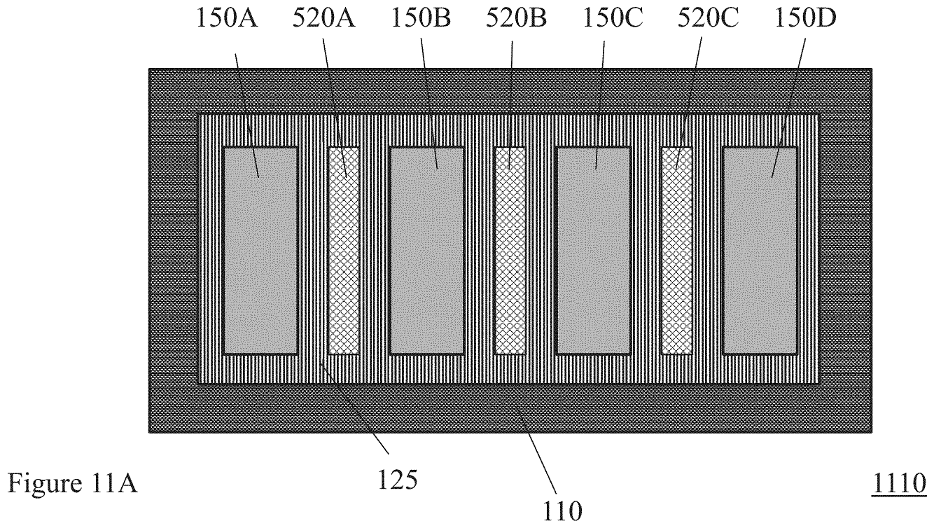

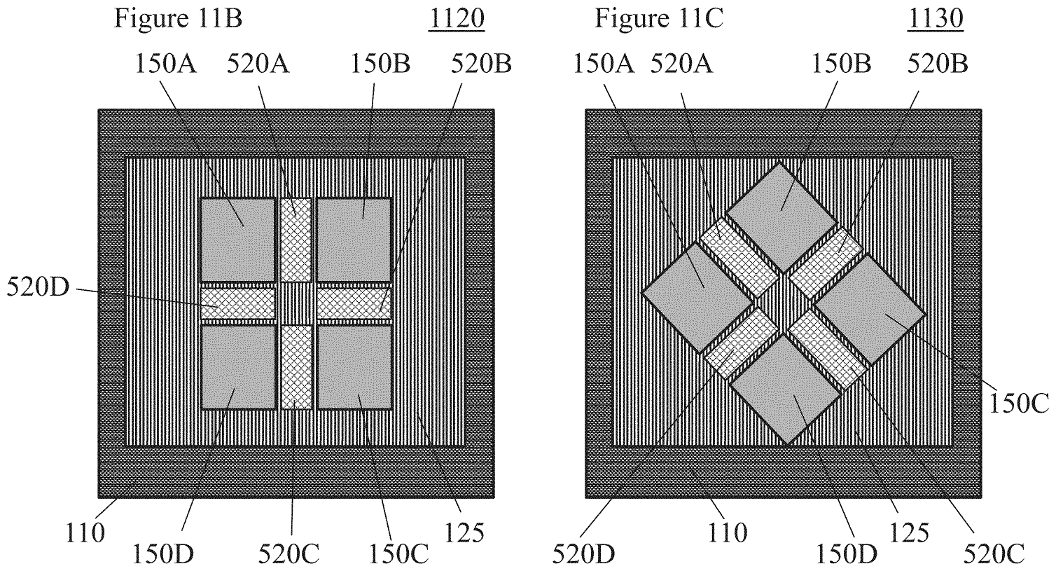

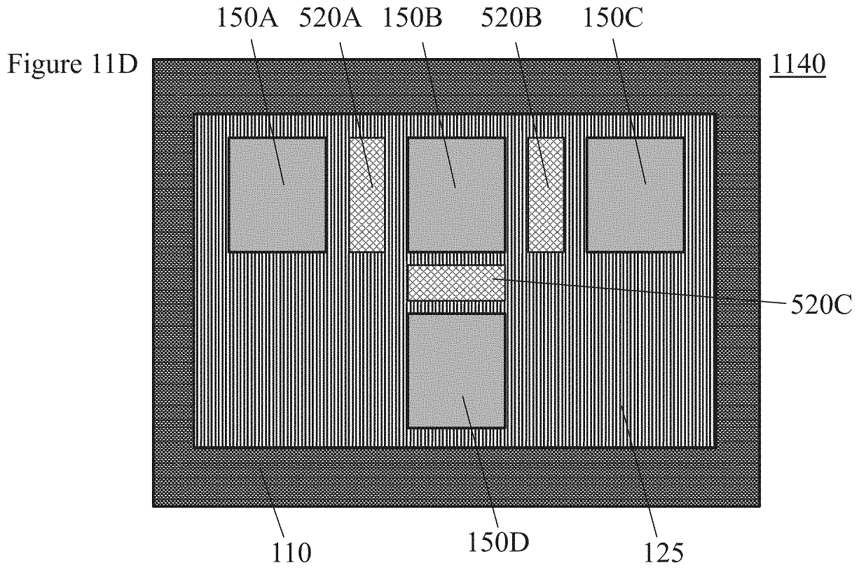

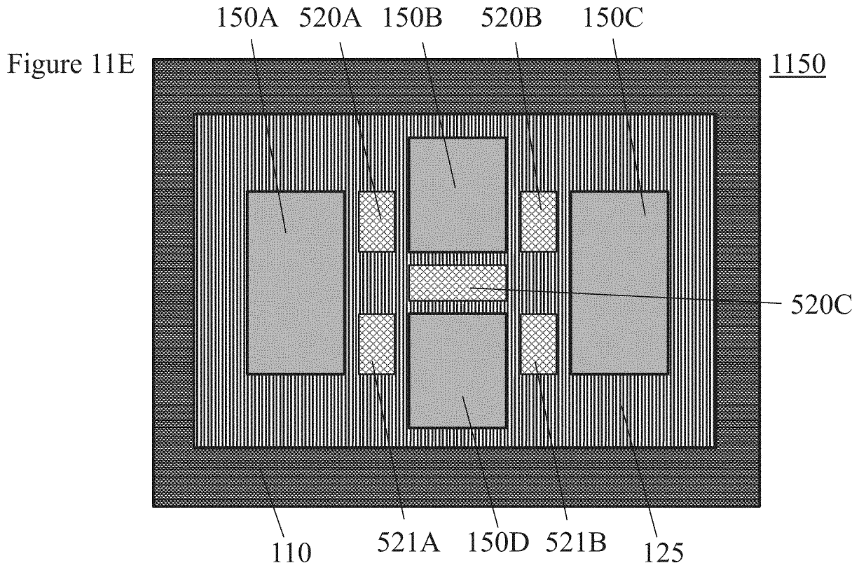

FIGS. 11A, 11B, 11C, 11D, and 11F show variations of molt-chip module (MCM) layouts with four chip/dies (150A, 150B, 150C, and 150D), typically 150).

FIG. 11A is a plan view of a molt-chip module (MCM) 1110 layout with the four chip/dies (150A, 150B, 150C, and 150D, typically 150) in a row with a respective shortened central lid rib, typically 520 between them. For example, shortened central lid rib 520A is between chip/dies 150A and 150B, as shortened central lid rib 520B is between chip/dies 150B and 150C, and shortened central lid rib 520C is between chip/dies 150C and 150D.

FIG. 11B is a molt-chip module (MCM) 1120 layout with the four chip/dies (150A, 150B, 150C, and 150D, typically 150) of approximately equal size and shape laid out in a rectangular or square pattern. Each chip/die 150 has a shortened central lid rib 520 between it and its adjacent neighbor on two sides. For example, shortened central lid rib 520A is between chip/dies 150A and 150B, as shortened central lid rib 520B is between chip/dies 150B and 150C, as shortened central lid rib 520C is between chip/dies 150C and 150D, and as shortened central lid rib 520D is between chip/dies 150D and 150A.

FIG. 11C is a molt-chip module (MCM) 1130 layout with the four chip/dies (150A, 150B, 150C, and 150D, typically 150) of approximately equal size and shape that are laid out in a rhombus or parallelogram pattern. This layout is the same as that in FIG. 11B but rotated counter-clockwise by 45 degrees.

FIG. 11D is a molt-chip module (MCM) 1140 layout with the four chip/dies (150A, 15013, 150C, and 150D, typically 150) of approximately equal size and shape laid out in a “T” pattern. Each chip/die 150 has a shortened central lid rib 520 between it and its adjacent neighbor on one side, except chip/die 150B that has a shortened central lid rib 520 on three sides. In this layout, shortened central lid rib 520A is between chip/dies 150A and 150B, as shortened central lid rib 520B is between chip/dies 150B and 150C, and as shortened central lid rib 520C is between chip/dies 150B and 150D.

FIG. 11E is a mull-chip module (MCM) 1150 layout with the four chip/dies (150A, 150B, 150C, and 150D, typically 150). Two first chips/dies, e.g. 150B and 150D, are of a smaller size than two of the second chip/dies, e.g. 150A and 150C. The chip/dies 150 are laid out in a “plus” pattern. The two first chip/dies, 150B and 150D have a shortened central lid rib 520C between them that is about equal to the short, adjacent sides of the two first chip dies, 150B and 150D. The longer two second chip/dies, 150A and 150C, each have there longer sides parallel to and in common with both the two first chip/dies, 150B and 150D. Shorter shortened central lib ribs 520 are between the common interfaces. For example, shorter shortened central lid ribs 520A is between chip/dies 150A and 150B, as shorter shortened central lid rib 521A is between chip/dies 150A and 150D. Further, shorter shortened central lid ribs 520B is between chip/dies 150B and 150C, as shorter shortened central lid rib 521B is between chip/dies 150C and 150D.

The concepts presented in FIGS. 9A, 9B, 10A, 10B, 10C, 11A, 11B, 11C, 11D, and 11E once disclosed to one skilled in the art can be extended to generic modules/packages with “n” number of chips/dies, e.g. to generic “nCMs”, where n is equal to two or more chip/dies 150. Embodiments presented in these Figures include a thicker region of variable thickness lid adhesive 525 between the shortened central lid rib, typically 520, and the substrate/chip carrier 110 and/or bridge 130.

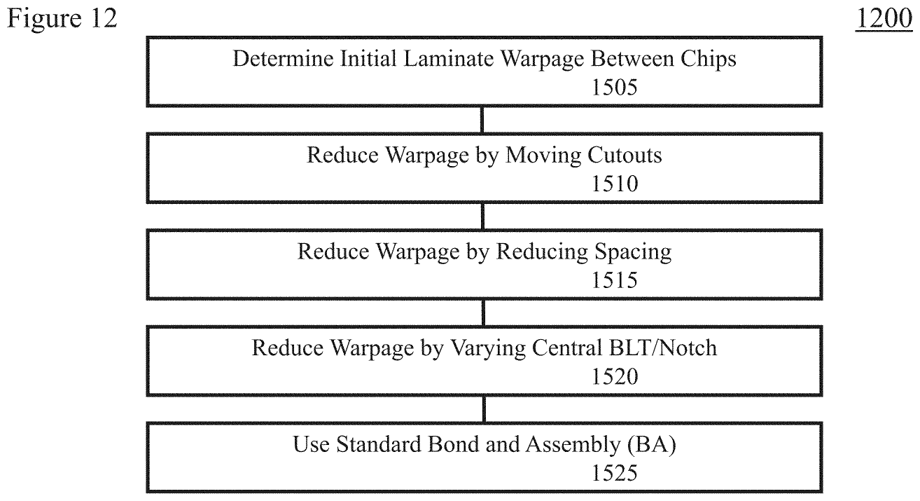

FIG. 12 is a flow chart showing the method steps of a process 1200 of making a module/package with a variable thickness adhesive.

The process 1200 begins with step 1505, a determination of laminate warpage between chips 150 for an initial module 100 design.

In step 1510, the warpage is reduced by moving cutouts 580 close (581A, 581B) to the spacing region 255 between the chips 150 away from the spacing region 255, if possible.

In step 1515, the die-to die spacing 250 is reduced as enabled by the shortened central lid rib 520.

In step 1520 a notch 650 is designed into the shortened central lid rib meeting the constraints defined above. The shortened central lid rib 520 with the notch 650 enables a variable thickness lid adhesive 525 that can reduce strains in selected regions with high strain.

As stated above, to achieve different thicknesses, sealband adhesive 125 and variable thickness lid adhesive 525 are dispensed sequentially, varying the dispense rate, and/or with multiple passes.

In this way varying thicknesses of sealband adhesive 125 and variable thickness lid adhesive 525 can be created without additional external stiffeners or curing steps before the lid 120 is attached. This enables use of standard bond and assembly (BA) techniques in step 1525.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. For example, the semiconductor devices, structures, and methods disclosed in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, expert and artificial intelligence systems, functional circuitry, etc. Systems and hardware incorporating the semiconductor devices are contemplated embodiments of the invention.

The terminology used herein was chosen to explain the principles of the embodiments and the practical application or technical improvement over technologies found in the marketplace or to otherwise enable others of ordinary skill in the art to understand the embodiments disclosed herein. Devices, components, elements, features, apparatus, systems, structures, techniques, and methods described with different terminology that perform substantially the same function, work in the substantial the same way, have substantially the same use, and/or perform the similar steps are contemplated as embodiments of this invention.

We claim:

1. A module of containing a plurality of components, comprising: one or more chip pairs each chip pair having a first semiconductor chip and a second semiconductor chip, each chip pair having a spacing forming a spacing region between the first and second semiconductor chips, the first and second semiconductor chips each having a chip back side;
a substrate on which the chip pairs are disposed;
a lid having a lid bottom side and one or more feet, the feet protruding from a periphery of the lid bottom side;
a sealband adhesive with a sealband adhesive thickness, the sealband adhesive adhering the feet to the substrate, so the chip pairs are under the lid bottom side and the chip back sides are in thermal contact with the lid bottom side; and
a variable thickness lid adhesive that connects the lid bottom side to the substrate in the spacing region, the variable thickness lid adhesive having a lid adhesive thickness,
wherein the lid adhesive thickness is greater than the sealband adhesive thickness by a delta thickness amount.

2. A module, as in claim 1, further comprising one or more bridges below the chips, one or more of the bridges being within the spacing and the variable thickness lid adhesive connecting one of the bridges to one of the lid regions.

1. A module, as in claim 1, where the sealband adhesive is made of one or more of the following materials: epoxies, Ablebond 84-3, Masterbond, Loctitle 965-1L, silicones, and Dow EA 6700.

4. A module, as in claim 1, where the variable thickness lid adhesive is made of one or more of the following materials: Masterbond and Loctitle 965-1L.

5. A module, as in claim 1, where the variable thickness lid adhesive stronger than the sealband adhesive.

6. A module, as in claim 1, where delta thickness amount is between 80 and 100 microns.

7. A module of containing a plurality of components, comprising:
one or more chip pairs each having a first semiconductor chip and a second semiconductor chip, each chip pair having a spacing forming a spacing region between the first and second semiconductor chips, the first and second semiconductor chips each having a chip back side;
a substrate on which the chip pairs are disposed;
a lid having a lid bottom side and one or more feet, the feet protruding from a periphery of the lid bottom side, the lid further having a shortened central lid rib with a bottom, the shorten central lid rib protruding an extension distance from the lid bottom side into the spacing region;
a sealband adhesive with a sealband adhesive thickness, the sealband adhesive adhering the feet to the substrate, so the chip pairs are under the lid bottom side and the chip back sides are in thermal contact with the lid bottom side; and
a variable thickness lid adhesive that connects the bottom to the substrate in the spacing region, the variable thickness lid adhesive having a lid adhesive thickness,
wherein the lid adhesive thickness is greater than the sealband adhesive thickness by a delta thickness amount.

8. A module, as in claim 7, where t d adhesive thickness is thickest between the semiconductor chips.

9. A module, as in claim 7, where the extension distance does not extend below the chip back side.

10. A module, as in claim 7, where the shorten central lid rib has a notch with a notch width and a notch thickness, the notch thickness being the amount of extension distance the notch reduces.

11. A module, as in claim 10, where the notch can be positioned anywhere along the shorten central lid rib.

12. A module, as in claim 10, where the notch width is equal to a side dimension of the chip.

13. A module, as in claim 10, where the notch thickness is between 50 micrometers and 100 μm.

14. A module, as in claim 10, where the notch thickness does not excess an amount that causes a Thermal Interface Material (TIM) strain to exceed a limit.

15. A module, as in claim 10, where three or more semiconductor chips are adjacent.

16. A module, as in claim 10, where three or more semiconductor chips are arranged in one or more of the following patterns: a row, a rectangle, a square, a rhombus, a parallelogram, a “T”, and a plus.

17. A method of making a semiconductor module comprising the steps of:
laying a sealband adhesive around a perimeter of the module, the sealband adhesive having a sealband adhesive thickness;
laying a lid adhesive with a lid adhesive thickness between two semiconductor chips disposed on a substrate in the module, the lid adhesive thickness being thicker than the sealband adhesive thickness by a delta thickness amount;
placing a lid on the substrate, the lid having a lid bottom side and one or more feet, the feet protruding from a periphery of the lid bottom side, the lid further having a shortened central lid rib with a bottom, the shorten central lid rib protruding an extension distance from the lid bottom side,
wherein the bottom is in contact with the lid adhesive and the feet are in contact with the sealband adhesive.

18. A method, as in claim 17, where the lid adhesive has multiple thicknesses.

19. A method, as in claim 17, where the lid adhesive is laid in one or more of the following steps: dispensed sequentially using an auger, dispensing sequentially using an air-pressure pumps, varying a dispensing rate, and dispensing with multiple passes.

20. A method, as in claim 17, where the lid is placed without curing the lid adhesive and sealband adhesive.
